(19) United States
(12) Patent Application Publication
(10) Pub. No.: US 2014/0272722 A1
(43) Pub. Date: Sep. 18, 2014

(54) COMPOSITION FOR FORMING RESIST UNDERLAYER FILM, RESIST UNDERLAYER FILM AND RESIST UNDERLAYER FILM-FORMING METHOD, AND PATTERN-FORMING METHOD

(71) Applicant: JSR CORPORATION, Tokyo (JP)

(72) Inventors: Shin-ya NAKAFUJI, Tokyo (JP); Satoru MURAKAMI, Tokyo (JP); Yoshio TAKIMOTO, Tokyo (JP); Kazuhiko KOMURA, Tokyo (JP); Masayuki MOTONARI, Tokyo (JP); Katsuhisa MIZOGUCHI, Tokyo (JP)

(73) Assignee: JSR CORPORATION, Tokyo (JP)

(21) Appl. No.: 14/290,744

(22) Filed: May 29, 2014

Related U.S. Application Data
(63) Continuation of application No. PCT/JP2012/080518, filed on Nov. 26, 2012.

(30) Foreign Application Priority Data
Dec. 1, 2011 (JP) 2011-264144

(51) Int. Cl. G03F 7/038; B05D 3/02

(52) U.S. Cl. CPC G03F 7/0384; B05D 3/0254
USPC 430/323; 528/211; 427/385.5; 524/611

(57) ABSTRACT

A composition for forming a resist underlayer film includes a polymer having a structural unit represented by a formula (1). Ar¹, Ar², Ar³ and Ar⁴ each independently represent a divalent aromatic hydrocarbon group or a divalent heteroaromatic group. A part or all of hydrogen atoms included in the divalent aromatic hydrocarbon group and the divalent heteroaromatic group represented by Ar¹, Ar², Ar³ or Ar⁴ may be substituted. R¹ represents a single bond or a divalent hydrocarbon group having 1 to 20 carbon atoms. A part or all of hydrogen atoms included in the divalent hydrocarbon group represented by R¹ may be substituted. The divalent hydrocarbon group represented by R¹ may have an ester group, an ether group or a carbonyl group in a structure thereof. Y represents a carbonyl group or a sulfonyl group. m is 0 or 1. n is 0 or 1.

[chemical structure]

### CROSS-REFERENCE TO RELATED APPLICATIONS

The present application is a continuation application of International Application No. PCT/JP2012/080518, filed Nov. 26, 2012, which claims priority to Japanese Patent Application No. 2011-264144, filed Dec. 1, 2011. The contents of these applications are incorporated herein by reference in their entirety.

### BACKGROUND OF THE INVENTION

1. Field of the Invention

The present invention relates to a composition for forming a resist underlayer film, a resist underlayer film and a resist underlayer film-forming method, and a pattern-forming method.

2. Discussion of the Background

In manufacturing semiconductor devices, multilayer resist processes have been employed for attaining a high degree of integration. In these processes, a composition for forming a resist underlayer film is first coated on a substrate to provide a resist underlayer film, and then a resist composition is coated on the resist underlayer film to provide a resist film. Thereafter, the resist film is exposed through a mask pattern by means of a stepping projection aligner (stepper) or the like, and developed with an appropriate developer solution to form a resist pattern. Subsequently, the resist underlayer film is dry-etched using the resist pattern as a mask, and further the substrate is dry-etched using the resultant resist underlayer film pattern as a mask, thereby enabling a desired pattern to be formed on the substrate. Resist underlayer films used in such multilayer resist processes are required to exhibit general characteristics such as optical characteristics and etching resistance.

In recent years, in order to further increase the degree of integration, miniaturization of patterns has been further in progress. Also in connection with the multilayer resist processes described above, structures of polymers, etc., contained in the composition for forming a resist underlayer film, and functional groups included in the polymers have been variously investigated (see Japanese Unexamined Patent Application, Publication No. 2004-177668).

Moreover, recently, multilayer resist processes in which a hard mask is provided on a resist underlayer film using CVD techniques have been investigated. Specifically, in these processes, a resist underlayer film is provided, and then an inorganic hard mask as an intermediate layer is provided on the resist underlayer film using a CVD technique. In a case where the inorganic hard mask is provided using the CVD technique, in particular in a case where a nitride film is provided, a substrate needs to be heated to a temperature of at least 300° C., and typically 400° C.

### SUMMARY OF THE INVENTION

According to one aspect of the present invention, a composition for forming a resist underlayer film includes a polymer having a structural unit represented by a formula (1).

[chemical structure]

In the formula (1), Ar¹, Ar², Ar³ and Ar⁴ each independently represent a divalent aromatic hydrocarbon group or a divalent heteroaromatic group, wherein a part or all of hydrogen atoms included in the divalent aromatic hydrocarbon group and the divalent heteroaromatic group represented by Ar¹, Ar², Ar³ or Ar⁴ are unsubstituted or substituted; R¹ represents a single bond or a divalent hydrocarbon group having 1 to 20 carbon atoms, wherein a part or all of hydrogen atoms included in the divalent hydrocarbon group represented by R¹ are unsubstituted or substituted, and wherein the divalent hydrocarbon group represented by R¹ has or does not have an ester group, an ether group or a carbonyl group in a structure thereof; Y represents a carbonyl group or a sulfonyl group; m is 0 or 1; and n is 0 or 1.

According to another aspect of the present invention, a resist underlayer film is formed from the composition.

According to further aspect of the present invention, a resist underlayer film-forming method includes applying the composition on a substrate to provide a coating film. The coating film is heated to provide a resist underlayer film.

According to further aspect of the present invention, a pattern-forming method includes applying the composition on a substrate to provide a resist underlayer film. A resist composition is applied on an upper face of the resist underlayer film to provide a resist film. The resist film is exposed through selective irradiation with a radioactive ray. The exposed resist film is developed to form a resist pattern. The resist underlayer film and the substrate are dry-etched sequentially using the resist pattern as a mask.

### DESCRIPTION OF THE EMBODIMENTS

According to an embodiment of the present invention made for solving the aforementioned problems, a composition for forming a resist underlayer film for use in a multilayer resist process (hereinafter, may be also merely referred to as “composition for forming a resist underlayer film” or “composition”) is provided, containing (A) a polymer having a structural unit (I) represented by the following formula (1) (hereinafter, may be also referred to as “polymer (A)),

[chemical structure]

wherein in the formula (1), Ar¹, Ar², Ar³ and Ar⁴ each independently represent a divalent aromatic hydrocarbon group or a divalent heteroaromatic group, wherein a part or all of hydrogen atoms included in the divalent aromatic hydrocarbon group and the divalent heteroaromatic group are unsubstituted or substituted; R¹ represents a single bond or a divalent hydrocarbon group having 1 to 20 carbon atoms, wherein a part or all of hydrogen atoms included in the divalent hydrocarbon group having 1 to 20 carbon atoms are unsubstituted or substituted, and wherein the divalent hydrocarbon group having 1 to 20 carbon atoms has or does not have an ester group, an ether group or a carbonyl group in a structure thereof; Y represents a carbonyl group or a sulfonyl group; m is 0 or 1; and n is 0 or 1.

When the composition for forming a resist underlayer film contains the polymer (A), a resist underlayer film formed from the composition sufficiently attains general characteristics such as optical characteristics and etching resistance, and additionally has superior heat resistance, solvent resistance and flexural resistance.

It is preferred that Ar¹, Ar², Ar³ and Ar⁴ in the above formula (1) are each independently represented by the following formula (2):

[chemical structure]

wherein in the formula (2), Q¹ represents an aromatic hydrocarbon group having a valency of (k+2) or a heteroaromatic group having a valency of (k+2); R² represents a halogen atom, a hydroxy group, a cyano group, a formyl group or a monovalent hydrocarbon group having 1 to 20 carbon atoms, wherein a part or all of hydrogen atoms included in the monovalent hydrocarbon group having 1 to 20 carbon atoms are unsubstituted or substituted with a halogen atom, a hydroxy group, a cyano group or a formyl group; and k is an integer of 0 to 6, wherein in a case where k is no less than 2, a plurality of R²s are identical or different.

When Ar¹, Ar², Ar³ and Ar⁴ thus represent the specific group, heat resistance and the like of a resist underlayer film formed from the composition for forming a resist underlayer film can be further enhanced.

It is preferred that m in the above formula (1) is 0, or that m in the above formula (1) is 1 and R¹ in the above formula (1) represents a single bond or is represented by the following formula (3):

[chemical structure]

wherein in the formula (3), Q² represents an aromatic hydrocarbon group having a valency of (a+2) or a heteroaromatic group having a valency of (a+2); Q³ represents an aromatic hydrocarbon group having a valency of (b+2) or a heteroaromatic group having a valency of (b+2); R³ and R⁴ each independently represent a halogen atom, a hydroxy group or a cyano group; a is an integer of 0 to 4; and b is an integer of 0 to 4, wherein in a case where R³ and R⁴ are each present in a plurality of number, a plurality of R^{a}s are identical or different with each other and a plurality of R⁴s are identical or different with each other.

When the structural unit (I) thus has a feature that it includes the specific group, the heat resistance and the like of the resist underlayer film formed from the composition for forming a resist underlayer film can be further improved.

It is preferred that the composition for forming a resist underlayer film further contains (B) a solvent. When the composition for forming a resist underlayer film thus further contains the solvent (B), coating properties of the composition can be improved.

The resist underlayer film according to another embodiment of the present invention is formed from the composition for forming a resist underlayer film. When the resist underlayer film is formed from the specific composition for forming a resist underlayer film, the resist underlayer film sufficiently attains general characteristics such as etching resistance and additionally has superior heat resistance, solvent resistance and flexural resistance.

According to still another embodiment of the present invention, a resist underlayer film-forming method includes:

(1) applying the composition for forming a resist underlayer film according to the embodiment of the present invention on a substrate to provide a coating film; and

(2) heating the coating film to provide a resist underlayer film.

When the resist underlayer film-forming method includes the specific steps, a resist underlayer film that sufficiently attains general characteristics such as etching resistance and additionally has superior heat resistance, solvent resistance and flexural resistance may be formed.

According to yet still another embodiment of the present invention, a pattern-forming method is provided, including:

(1) applying the composition for forming a resist underlayer film according to the embodiment of the present invention on a substrate to provide a resist underlayer film;

(2) applying a resist composition on an upper face of the resist underlayer film to provide a resist film;

(3) exposing the resist film through selective irradiation with a radioactive ray;

(4) developing the exposed resist film to form a resist pattern; and

(5) dry-etching the resist underlayer film and the substrate sequentially using the resist pattern as a mask.

When the pattern-forming method includes the specific steps, the pattern-forming method enables a resist underlayer film that sufficiently attains general characteristics such as etching resistance and additionally has superior heat resistance, solvent resistance and flexural resistance to be provided easily and reliably. As a result, the pattern-forming method allows for the formation of a finer pattern on a substrate.

The pattern-forming method may further include, after the step (1) and before the step (2):

(1′) providing an intermediate layer on the resist underlayer film, and the step (5) further includes dry-etching the intermediate layer.

When the pattern-forming method further includes the specific step, an intermediate layer that exhibits a desired function such as an antireflecting function and etching resistance may be provided. As a result, a finer pattern may be formed on a substrate.

According to the composition for forming a resist underlayer film for use in a multilayer resist process of the embodiment of the present invention, a resist underlayer film that sufficiently attains general characteristics such as etching resistance and additionally has superior heat resistance, solvent resistance and the like can be provided. Therefore, the composition for forming a resist underlayer film, the resist underlayer film and the resist underlayer film-forming method, and the pattern-forming method according to the embodiment of the present invention may be suitably used in pattern-forming processes that employ a multilayer resist process for semiconductor devices in which miniaturization of patterns has been further in progress. The embodiments will now be described in detail.

### Composition for Forming Resist Underlayer Film for Use in Multilayer Resist Process

A composition for forming a resist underlayer film for use in a multilayer resist process according to an embodiment of the present invention contains (A) a polymer. The composition for forming a resist underlayer film may also contain (B) a solvent as a favorable component. Furthermore, the composition for forming a resist underlayer film may contain other optional component such as (C) an acid generating agent, (D) a crosslinking agent, (E) a surfactant and (F) an adhesion aid, within a range not leading to impairment of the effects of the present invention. It is to be noted that the composition for forming a resist underlayer film may contain two or more types of polymers (A). Hereinafter, each component will be explained in detail.

### (A) Polymer

The polymer (A) is a polymer that includes a structural unit (I). The polymer (A) may also include other structural unit, within a range not leading to impairment of the effects of the present invention. It is to be noted that the polymer (A) may have two or more types of each structural unit, and in such a case, the polymer (A) may be either a random copolymer or a block copolymer. Hereinafter, each structural unit will be explained in detail.

### Structural Unit (I)

The structural unit (I) is a structural unit represented by the above formula (1). When the polymer (A) has the specific structural unit, a resist underlayer film formed from the composition for forming a resist underlayer film sufficiently attains general characteristics such as etching resistance and additionally has superior heat resistance, solvent resistance and flexural resistance. Further, it is presumed that such superior heat resistance and the like is attributed to a direct connection of the ether group to the aromatic hydrocarbon group or the heteroaromatic group by means of two covalent bonds in the main chain of the polymer (A), leading to stabilization of the polymer (A).

In the above formula (1), Ar¹, Ar², Ar³ and Ar⁴ each independently represent a divalent aromatic hydrocarbon group or a divalent heteroaromatic group, wherein a part or all of hydrogen atoms included in the divalent aromatic hydrocarbon group and the divalent heteroaromatic group are unsubstituted or substituted; R¹ represents a single bond or a divalent hydrocarbon group having 1 to 20 carbon atoms, wherein a part or all of hydrogen atoms included in the divalent hydrocarbon group having 1 to 20 carbon atoms are unsubstituted or substituted, and wherein the divalent hydrocarbon group having 1 to 20 carbon atoms has or does not have an ester group, an ether group or a carbonyl group in a structure thereof; Y represents a carbonyl group or a sulfonyl group; m is 0 or 1; and n is 0 or 1.

The divalent aromatic hydrocarbon group which may be represented by Ar¹, Ar², Ar³ and Ar⁴ is preferably a divalent aromatic hydrocarbon group having 6 to 20 carbon atoms, and examples thereof include a phenylene group, a naphthylene group, an anthranylene group, and the like.

The divalent heteroaromatic group which may be represented by Ar¹, Ar², Ar³ and Ar⁴ is preferably a divalent heteroaromatic group having 3 to 20 carbon atoms, and examples thereof include a group derived from a heteroaromatic compound such as furan, pyrrole, thiophene, phosphole, pyrazole, oxazole, isoxazole, thiazole, pyridine, pyrazine, pyrimidine, pyridazine, triazine, indole, quinoline or acridine by eliminating two hydrogen atoms therefrom, and the like.

Examples of the substituent that may be introduced the divalent aromatic hydrocarbon group and the divalent heteroaromatic group include halogen atoms, a hydroxy group, a cyano group, a nitro group, a formyl group, monovalent organic groups, or the like.

Examples of the halogen atom include a fluorine atom, a chlorine atom, a bromine atom, an iodine atom, and the like.

Examples of the monovalent organic group include monovalent groups derived from a monovalent aromatic group having 3 to 20 carbon atoms by combining with —CO—, —COO—, —COO—, —O—, —NR—, —CS—, —S—, —SO—, —SO₂— or a combination thereof, a monovalent aromatic group having 3 to 20 carbon atoms, and the like, and furthermore groups derived from the above-mentioned monovalent group and monovalent aromatic group by substituting a hydrogen atom included therein with a substituent. R in —NR— represents a hydrogen atom or a monovalent organic group having 1 to 10 carbon atoms. Moreover, examples of the substituent include a hydroxy group, a cyano group, a carboxy group, an ethynyl group, and the like.

The monovalent aromatic group having 3 to 20 carbon atoms is preferably a monovalent aromatic hydrocarbon group having 6 to 20 carbon atoms or a monovalent heteroaromatic group having 3 to 20 carbon atoms. Examples of the monovalent aromatic hydrocarbon group having 6 to 20 carbon atoms include a phenyl group, a naphthyl group, an anthranyl group, and the like. Moreover, examples of the monovalent heteroaromatic group having 3 to 20 carbon atoms include groups derived from a heteroaromatic compound such as furan, pyrrole, thiophene, phosphole, pyrazole, oxazole, isoxazole, thiazole, pyridine, pyrazine, pyrimidine, pyridazine, triazine, indole, quinoline and acridine by eliminating a hydrogen atom therefrom, and the like.

Examples of the monovalent group derived from a monovalent aromatic group having 3 to 20 carbon atoms by combining with —CO—, —COO—, —COO—, —O—, —NR—, —CS—, —S—, —SO—, —SO₂— or a combination thereof include a phenoxy group, a naphthyloxy group, an anthranyloxy group, an anilino group, and the like.

It is preferred that Ar¹, Ar², Ar³ and Ar⁴ in the above formula (1) each independently represent a group represented by the above formula (2). When Ar¹, Ar², Ar³ and Ar⁴ each represent the specific group, the heat resistance and the like of the resist underlayer film can be further enhanced.

In the above formula (2), Q¹ represents an aromatic hydrocarbon group having a valency of (k+2) or a heteroaromatic group having a valency of (k+2); R² represents a halogen atom, a hydroxy group, a cyano group, a formyl group or a monovalent hydrocarbon group having 1 to 20 carbon atoms, wherein a part or all of hydrogen atoms included in the monovalent hydrocarbon group having 1 to 20 carbon atoms are unsubstituted or substituted with a halogen atom, a hydroxy group, a cyano group or a formyl group; and k is an integer of 0 to 6, wherein in a case where k is no less than 2, a plurality of R²s are identical or different.

Examples of the aromatic hydrocarbon group having a valency of (k+2) which may be represented by Q¹ include groups derived from a divalent aromatic hydrocarbon group by eliminating k hydrogen atom(s) therefrom, and the like. Examples of the divalent aromatic hydrocarbon group include the divalent aromatic hydrocarbon groups exemplified in relation to Ar¹, Ar², Ar³ and Ar⁴, and the like.

Examples of the heteroaromatic group having a valency of (k+2) which may be represented by Q¹ include groups derived from a divalent heteroaromatic group by eliminating k hydrogen atom(s) therefrom, and the like. Examples of the divalent heteroaromatic group include the divalent heteroaromatic groups exemplified in relation to Ar¹, Ar², Ar³ and Ar⁴, and the like. Examples of the halogen atom which may be represented by R² include a fluorine atom, a chlorine atom, a bromine atom, an iodine atom, and the like.

Examples of the monovalent hydrocarbon group having 1 to 20 carbon atoms which may be represented by R² include alkyl groups having 1 to 20 carbon atoms, monovalent alicyclic hydrocarbon groups having 3 to 20 carbon atoms, monovalent aromatic hydrocarbon groups having 6 to 20 carbon atoms, and the like.

Examples of the alkyl group having 1 to 20 carbon atoms include linear alkyl groups such as a methyl group, an ethyl group, a n-propyl group and a n-butyl group; branched alkyl groups such as an i-propyl group, an i-butyl group, a sec-butyl group and a t-butyl group; and the like.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group and a cyclodecadienyl group; polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, a norbornyl group and an adamantyl group; and the like.

Examples of the monovalent aromatic hydrocarbon group having 6 to 20 carbon atoms include a phenyl group, a biphenyl group, a naphthyl group, and the like.

In the above formula (2), it is preferred that Q¹s in Ar¹ and Ar² each independently have a benzene ring or a naphthalene ring.

Examples of the divalent hydrocarbon group having 1 to 20 carbon atoms which may be represented by R¹ include alkanediyl groups having 1 to 20 carbon atoms, divalent alicyclic hydrocarbon groups having 3 to 20 carbon atoms, divalent aromatic hydrocarbon groups having 6 to 20 carbon atoms, and divalent groups derived by combining two or more of an alkanediyl group having 1 to 20 carbon atoms, a divalent alicyclic hydrocarbon group having 3 to 20 carbon atoms and a divalent aromatic hydrocarbon group having 6 to 20 carbon atoms, and the like.

Examples of the alkanediyl group having 1 to 20 carbon atoms include a methanediyl group, an ethanediyl group, a propanediyl group, a butanediyl group, a pentanediyl group, a hexanediyl group, and the like.

Examples of the divalent alicyclic hydrocarbon group having 3 to 20 carbon atoms include monocyclic saturated hydrocarbon groups such as a cyclopropanediyl group, a cyclobutanediyl group and a cyclopentanediyl group; a monocyclic unsaturated hydrocarbon group such as a cyclobutenediyl group, a cyclopentenediyl group and a cyclohexenediyl group; polycyclic saturated hydrocarbon groups such as a bicyclo[2.2.1]heptanediyl group, a bicyclo[2.2.2]octanediyl group and a tricyclo[5.2.1.0^{2,6}]decanediyl group; polycyclic unsaturated hydrocarbon groups such as a bicyclo[2.2.1]heptenediyl group, a bicyclo[2.2.2]octenediyl group and a tricyclo[5.2.1.0^{2,6}]decenediyl group; and the like.

Examples of the divalent aromatic hydrocarbon group having 6 to 20 carbon atoms include a phenylene group, a naphthylene group, an anthranylene group, and the like.

Examples of the divalent group derived by combining two or more of an alkanediyl group having 1 to 20 carbon atoms, a divalent alicyclic hydrocarbon group having 3 to 20 carbon atoms and a divalent aromatic hydrocarbon group having 6 to 20 carbon atoms include divalent groups derived by combining two or more types of groups exemplified as the alkanediyl group having 1 to 20 carbon atoms, the divalent alicyclic hydrocarbon group having 3 to 20 carbon atoms and the divalent aromatic hydrocarbon group having 6 to 20 carbon atoms, and the like.

Examples of the substituent that may be introduced in the divalent hydrocarbon group having 1 to 20 carbon atoms which may be represented by R¹ include the groups exemplified as the substituent that may be introduced in the divalent aromatic hydrocarbon group and the divalent heteroaromatic group.

It is preferred that m in the above formula (1) is 0, or that m in the above formula (1) is 1 and R¹ in the above formula (1) represents a single bond or is represented by the above formula (3) (hereinafter, a structural unit (I) having this structure may be also referred to, in particular, as “structural unit (I′)”). When the structural unit (I) is represented by the structural unit (I′), the heat resistance and the like of the resist underlayer film formed from the composition for forming a resist underlayer film can be further improved.

In the above formula (3), Q² represents an aromatic hydrocarbon group having a valency of (a+2) or a heteroaromatic group having a valency of (a+2); Q³ represents an aromatic hydrocarbon group having a valency of (b+2) or a heteroaromatic group having a valency of (b+2); R³ and R⁴ each independently represent a halogen atom, a hydroxy group or a cyano group; a is an integer of 0 to 4; b is an integer of 0 to 4, wherein in a case where R³ and R⁴ are each present in a plurality of number, a plurality of R³s are identical or different with each other and a plurality of R⁴s are identical or different with each other.

Examples of the aromatic hydrocarbon group having a valency of (a+2) which may be represented by Q² include groups derived from a divalent aromatic hydrocarbon group by eliminating a hydrogen atom(s) therefrom, and the like. Examples of the divalent aromatic hydrocarbon group include the divalent aromatic hydrocarbon groups exemplified in relation to Ar¹, Ar², Ar³ and Ar⁴, and the like.

Examples of the heteroaromatic group having a valency of (a+2) which may be represented by Q² include groups derived from a divalent heteroaromatic group by eliminating a hydrogen atom(s) therefrom, and the like. Examples of the divalent heteroaromatic group include the divalent heteroaromatic groups exemplified in relation to Ar¹, Ar², Ar³ and Ar⁴, and the like.

Examples of the aromatic hydrocarbon group having a valency of (b+2) which may be represented by Q³ include groups derived from a divalent aromatic hydrocarbon group by eliminating b hydrogen atom(s) therefrom, and the like. Examples of the divalent aromatic hydrocarbon group include the divalent aromatic hydrocarbon groups exemplified in relation to Ar¹, Ar², Ar³ and Ar⁴, and the like.

Examples of the heteroaromatic group having a valency of (b+2) which may be represented by Q³ include groups derived from a divalent heteroaromatic group by eliminating b hydrogen atom(s) therefrom, and the like. Examples of the divalent heteroaromatic group include the divalent heteroaromatic groups exemplified in relation to Ar¹, Ar², Ar³ and Ar⁴, and the like.

Examples of the halogen atom which may be represented by R³ and R⁴ include those exemplified as the halogen atom which may be represented by R².

Examples of the structural unit (I) include structural units represented by the following formulae (1-1) to (1-15), and the like.

[chemical structure]

[chemical structure]

[chemical structure]

Among these, the structural units represented by the formulae (1-1) to (1-14) which fall under the structural unit (I′) are preferred.

The proportion of structural unit (I) contained with respect to the total structural units in the polymer (A) falls within a range of preferably no less than 60 mol % and no greater than 100 mol %, and more preferably no less than 80 mol % and no greater than 100 mol %. Furthermore, the proportion of structural unit (I′) contained with respect to the total structural units in the polymer (A) particularly preferably falls within a range of no less than 80 mol % and no greater than 100 mol %. When the proportion of the structural unit (I) and structural unit (I′) contained falls within the above specific range, the heat resistance and the like of the resist underlayer film can be effectively enhanced.

### Other Structural Unit

The polymer (A) may include other structural unit within a range not leading to impairment of the effects of the present invention.

### Method for Synthesis of Polymer (A)

Examples of the method for synthesis of the polymer (A) include a method in which a component (a) that includes a compound represented by the following formula (4) is reacted with an alkali metal or alkali metal compound in an organic solvent to obtain an alkali metal salt of the component (a), and thereafter the alkali metal salt obtained is reacted with a component (b) that includes a compound represented by the following formula (5). Further, when the component (a) is reacted with the alkali metal or alkali metal compound in the presence of the component (b), the alkali metal salt of the component (a) is allowed to react with the component (b). The polymer obtained after the reaction may be recovered through a reprecipitation process. An alcohol solvent and the like may be used as a solvent for reprecipitation.

[chemical structure]

In the above formula (4), Ar¹, Ar², R¹ and m are as defined in the above formula (1).

In the above formula (5), Ar³, Ar⁴, Y and n are as defined in the above formula (1); and Xs each independently represent a halogen atom.

Examples of the halogen atom include a fluorine atom, a chlorine atom, a bromine atom, an iodine atom, and the like. Among these, a fluorine atom and a chlorine atom are preferred.

In the above formula (5), in a case where n is 0 and Ar⁴ represents an aromatic hydrocarbon group, it is preferred that a part or all of hydrogen atoms included in the aromatic hydrocarbon group are substituted with a cyano group. When the cyano group is directly bound to the aromatic ring of Ar⁴, the reaction of the component (a) with the component (b) may be facilitated due to an electron withdrawing nature of the cyano group.

Examples of the alkali metal used in the reaction include lithium, potassium, sodium, and the like.

Examples of the alkali metal compound used in the reaction include alkali metal hydrides such as lithium hydride, potassium hydride and sodium hydride; alkali metal hydroxides such as lithium hydroxide, potassium hydroxide and sodium hydroxide; alkali metal carbonates such as lithium carbonate, potassium carbonate and sodium carbonate; alkali metal hydrogencarbonates such as lithium hydrogencarbonate, potassium hydrogencarbonate and sodium hydrogencarbonate; and the like. These alkali metal compounds may be used either alone, or in combination of two or more types thereof.

The alkali metal or alkali metal compound is used in such an amount that the amount of the metal atom in the alkali metal or alkali metal compound is typically 1 to 3-fold equivalents, preferably 1.1 to 2-fold equivalents, and more preferably 1.2 to 1.5-fold equivalents with respective to all —OH in the component (a).

Examples of the organic solvent used in the reaction include dimethylacetamide, dimethylformamide, N-methyl-2-pyrrolidone, 1,3-dimethyl-2-imidazolidinone, γ-butyrolactone, sulfolane, dimethyl sulfoxide, diethyl sulfoxide, dimethyl sulfone, diethyl sulfone, diisopropyl sulfone, diphenyl sulfone, diphenyl ether, benzophenone, dialkoxybenzenes in which the alkoxy group has 1 to 4 carbon atoms, and trialkoxybenzenes in which the alkoxy group has 1 to 4 carbon atoms, and the like. Among these solvents, polar organic solvents having a high relative permittivity such as N-methyl-2-pyrrolidone, dimethylacetamide, sulfolane, diphenyl sulfone and dimethyl sulfoxide are preferred. The organic solvents may be used either alone, or in combination of two or more types thereof.

Furthermore, in the reaction, a solvent that forms an azeotropic mixture with water such as benzene, toluene, xylene, hexane, cyclohexane, octane, chlorobenzene, dioxane, tetrahydrofuran, anisole and phenetole may be further used. These solvents may be used either alone, or in combination of two or more types thereof.

It is to be noted that the component (a) may contain at least one of compounds represented by the following formulae as a part of the compound represented by the above formula (4) in light of the improvement of solubility of the component (a) in a solvent.

[chemical structure]

In regard to the proportion of the component (a) and the component (b) used, the proportion of the component (a) with respect to the sum of the proportions of the component (a) and the component (b) being 100 mol % falls within a range of preferably no less than 45 mol % and no greater than 55 mol %, more preferably no less than 48 mol % and no greater than 50 mol %, and particularly preferably no less than 48 mol % and less than 50 mol %. The proportion of the component (b) with respect to the sum of the proportions of the component (a) and the component (b) being 100 mol % falls within a range of preferably no less than 45 mol % and no greater than 55 mol %, more preferably no less than 50 mol % and no greater than 52 mol %, and particularly preferably greater than 50 mol % and no greater than 52 mol %.

The reaction temperature falls within a range of preferably 60° C. to 250° C., and more preferably 80° C. to 200° C. The reaction time falls within a range of preferably 15 min to 100 hours, and more preferably 1 hour to 24 hours.

The polystyrene equivalent weight average molecular weight (Mw) of the polymer (A) as determined by gel permeation chromatography (GPC) is preferably 1,000 to 20,000, more preferably 1,500 to 15,000, and particularly preferably 2,000 to 12,000.

### (B) Solvent

The solvent (B) is a favorable component which may be contained in the composition for forming a resist underlayer film. The solvent (B) is not particularly limited as long as the solvent (B) can dissolve or disperse therein the polymer (A) and the optional component contained as needed. When the composition for forming a resist underlayer film further contains the solvent (B), the coating properties thereof can be improved.

Examples of the solvent (B) include alcohol solvents, ketone solvents, amide solvents, ether solvents, ester solvents, and the like. It is to be noted that the solvent (B) may be used either alone, or in combination of two or more types thereof.

Examples of the alcohol solvent include monohydric alcohol solvents such as methanol, ethanol, n-propanol, iso-propanol, n-butanol, iso-butanol, sec-butanol, t-butanol, n-pentanol, iso-pentanol, sec-pentanol and t-pentanol; polyhydric alcohol solvents such as ethylene glycol, 1,2-propylene glycol, 1,3-butylene glycol, 2,4-pentanediol, 2-methyl-2,4-pentanediol, 2,5-hexanediol and 2,4-heptanediol; and the like.

Examples of the ketone solvent include aliphatic ketone solvents such as acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, di-iso-butyl ketone and trimethylnonanone; cyclic ketone solvents such as cyclopentanone, cyclohexanone, cycloheptanone, cyclooctanone and methylcyclohexanone; 2,4-pentanedione; acetonyl acetone; diacetone alcohol; acetophenone; methyl n-amyl ketone; and the like.

Examples of the amide solvent include 1,3-dimethyl-2-imidazolidinone, N-methylformamide, dimethylformamide, diethylformamide, acetamide, N-methylacetamide, dimethylacetamide, N-methylpropionamide, N-methyl-2-pyrrolidone, and the like.

Examples of the ether solvent include alkyl ethers of polyhydric alcohols such as ethylene glycol monomethyl ether, ethylene glycol monoethyl ether and ethylene glycol dimethyl ether; alkyl ether acetates of polyhydric alcohols such as ethylene glycol monomethyl ether acetate, ethylene glycol monoethyl ether acetate and propylene glycol methyl ether acetate; aliphatic ethers such as diethyl ether, dipropyl ether, dibutyl ether, butyl methyl ether, butyl ethyl ether and diisoamyl ether; aliphatic-aromatic ethers such as anisole and phenyl ethyl ether; cyclic ethers such as tetrahydrofuran, tetrahydropyran and dioxane; and the like.

Examples of the ester solvent include diethyl carbonate, propylene carbonate, methyl lactate, ethyl lactate, methyl acetate, ethyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, and the like.

Among these solvents, cyclohexanone, propylene glycol methyl ether acetate, cyclopentanone, γ-butyrolactone, ethyl lactate, methyl n-amyl ketone and mixed solvents thereof are preferred.

### Other Optional Components

The composition for forming a resist underlayer film may contain, in addition to the polymer (A), which is an essential component, and the solvent (B), which is a favorable component, other optional component (for example, (C) an acid generating agent, (D) a crosslinking agent, (E) a surfactant, (F) an adhesion aid, or the like) within a range not leading to impairment of the effects of the present invention. Moreover, the content of the other optional component may be appropriately selected depending on the purpose thereof.

### (C) Acid Generating Agent

The acid generating agent (C) is a component that generates an acid therefrom by an action of heat and/or lights and facilitates crosslinking of the polymer (A). When the composition for forming a resist underlayer film contains the acid generating agent (C), the crosslinking reaction of the polymer (A) may be facilitated and the hardness of the resist underlayer film can be further enhanced. It is to be noted that the acid generating agent (C) may be used either alone, or in combination of two or more types thereof.

Examples of the acid generating agent (C) include onium salt compounds, sulfonimide compounds, and the like. Among these, onium salt compounds are preferred.

Examples of the onium salt compound include sulfonium salts, tetrahydrothiophenium salts, iodonium salts, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, and the like. Among these, triphenylsulfonium trifluoromethanesulfonate, triphenylsulfonium nonafluoro-n-butanesulfonate, triphenylphosphonium 1,1,2,2-tetrafluoro-6-(1-adamantanecarbonyloxy)-hexane-1-sulfonate and 4-cyclohexylphenyldiphenylsulfonium nonafluoro-n-butanesulfonate are preferred.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydro thiophenium 2-bicyclo[2.2.1]hept-2-yl-1,1,2,2-tetrafluoroethanesulfonate, and the like. Among these tetrahydrothiophenium salts, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate and 1-(3,5-dimethyl-4-hydroxyphenyl)tetrahydrothiophenium nonafluoro-n-butanesulfonate are preferred.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like. Among these iodonium salts, bis(4-t-butylphenyl)iodonium nonafluoro-n-butanesulfonate is preferred.

Examples of the sulfonimide compound include N-(trifluoromethanesulfonyloxy)bicyclo[2.2.1]hept-5-ene-2,3-dicarboxylmide, N-(nonafluoro-n-butanesulfonyloxy)bicyclo[2.2.1]hept-5-ene-2,3-dicarboxylmide, N-(perfluoro-n-octanesulfonyloxy)bicyclo[2.2.1]hept-5-ene-2,3-dicarboxylmide, N-(2-bicyclo[2.2.1]hept-2-yl-1,1,2,2-tetrafluoroethanesulfonyloxy)bicyclo[2.2.1]hept-5-ene-2,3-dicarboxylmide, and the like.

In a case where the acid generating agent (C) is contained, the amount of the acid generating agent (C) contained with respect to 100 parts by mass of the polymer (A) (or with respect to 100 parts by mass of the total polymer, provided that a polymer other than the polymer (A) is further contained) falls within a range of preferably no less than 1 part by mass and no greater than 20 parts by mass, and more preferably no less than 3 parts by mass and no greater than 10 parts by mass. When the amount of the acid generating agent (C) contained falls within the above range, the crosslinking reaction may be effectively facilitated.

### (D) Crosslinking Agent

The crosslinking agent (D) is a component that forms a bond with a resin and/or other crosslinking agent molecule in a blend composition by an action of heat and/or an acid. When the composition for forming a resist underlayer film contains the crosslinking agent (D), the hardness of the resist underlayer film can be increased. It is to be noted that the crosslinking agent (D) may be used either alone, or in combination of two or more types thereof

Examples of the crosslinking agent (D) include polyfunctional (meth)acrylate compounds, epoxy compounds, hydroxymethyl group-substituted phenol compounds, alkoxyalkyl group-containing phenol compounds, compounds having an alkoxyalkylated amino group, random copolymers of acenaphthylene with hydroxymethylacenaphthylene, compounds represented by the following formulae (6-1) to (6-12), and the like.

Examples of the polyfunctional(meth)acrylate compound include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, bis(2-hydroxyethyl)isocyanurate di(meth)acrylate, and the like.

Examples of the epoxy compound include novolac epoxy resins, bisphenol epoxy resins, alicyclic epoxy resins, aliphatic epoxy resins, and the like.

Examples of the hydroxymethyl group-substituted phenol compound include 2-hydroxymethyl-4,6-dimethylphenol, 1,3,5-trihydroxymethylbenzene, 3,5-dihydroxymethyl-4-methoxytoluene (2,6-bis(hydroxymethyl)-p-cresol), and the like.

Examples of the alkoxyalkyl group-containing phenol compound include a methoxymethyl group-containing phenol compound, an ethoxymethyl group-containing phenol compound, and the like.

Examples of the compound having an alkoxyalkylated amino group include nitrogen-containing compounds having a plurality of active methylol groups in a molecule thereof wherein the hydrogen atom of the hydroxyl group of at least one of the methylol groups is substituted with an alkyl group such as a methyl group or a butyl group, and the like; examples thereof include (poly)methylolated melamines, (poly)methylolated glycolurils, (poly)methylolated benzoguanamines, (poly)methylolated ureas, and the like. It is to be noted that a mixture constituted with a plurality of substituted compounds described above may be used as the compound having an alkoxyalkylated amino group, and the compound having an alkoxyalkylated amino group may contain an oligomer component formed through partial self-condensation thereof.

[chemical structure]

[chemical structure]

In the above formulae, Me, Et and Ac represent a methyl group, an ethyl group and an acetyl group, respectively.

It is to be noted that the compounds represented by the above formulae (6-1) to (6-12) each may be synthesized with reference to the following documents.

The compound represented by the formula (6-1):

Guo, Qun-Sheng; Lu, Yong-Na; Liu, Bing; Xiao, Jian; and Li, Jin-Shan, Journal of Organometallic Chemistry, 2006, vol. 691, #6, p. 1282-1287

The compound represented by the formula (6-2):

Badar, Y. et al., Journal of the Chemical Society, 1965, p. 1412-1418

The compound represented by the formula (6-3):

Hsieh, Jen-Chieh; and Cheng, Chien-Hong, Chemical Communications (Cambridge, United Kingdom), 2008, #26, p. 2992-2994

The compound represented by the formula (6-4):

Japanese Unexamined Patent Application, Publication No. H5-238990

The compound represented by the formula (6-5):

Bacon, R. G. R.; and Bankhead, R., Journal of the Chemical Society, 1963, p. 839-845

The compounds represented by the formulae (6-6), (6-8), (6-11) and (6-12): Macromolecules, 2010, vol. 43, p. 2832-2839

The compounds represented by the formulae (6-7), (6-9) and (6-10):

Polymer Journal, 2008, vol. 40, No. 7, p. 645-650; and Journal of Polymer Science Part A, Polymer Chemistry, Vol. 46, p. 4949-4958

Among these crosslinking agents, a methoxymethyl group-containing phenol compound, a compound having an alkoxyalkylated amino group, and a random copolymer of acenaphthylene with hydroxymethylacenaphthylene are preferred.

In a case where the crosslinking agent (D) is contained, the amount of the crosslinking agent (D) contained with respect to 100 parts by mass of the polymer (A) (or with respect to 100 parts by mass of the total polymer, provided that a polymer other than the polymer (A) is further contained) falls within a range of preferably no less than 0.5 parts by mass and no greater than 50 parts by mass, more preferably no less than 1 part by mass and no greater than 40 parts by mass, and still more preferably no less than 2 parts by mass and no greater than 35 parts by mass. When the amount of the crosslinking agent (D) contained falls within the above range, the crosslinking reaction may be allowed to proceed effectively.

### (E) Surfactant

The surfactant (E) is a component that improves coating properties. When the composition for forming a resist underlayer film contains the surfactant (E), uniformity of the surface of the resist underlayer film provided may be improved, and occurrence of the unevenness of coating can be inhibited. It is to be noted that the surfactant (E) may be used either alone, or in combination of two or more types thereof.

Examples of the surfactant (E) include a nonionic surfactant such as polyoxyethylene lauryl ether, polyoxyethylene stearyl ether, polyoxyethylene oleyl ether, polyoxyethylene n-octyl phenyl ether, polyoxyethylene n-nonyl phenyl ether, polyethylene glycol dilaurate, polyethylene glycol distearate, as well as commercially available products such as KP341 (manufactured by Shin-Etsu Chemical Co., Ltd.), Polyflow No. 75 and No. 95 (each manufactured by Kyoeisha Chemical Co., Ltd.), F-top EF101, EF204, EF303 and EF352 (each manufactured by Tochem Products Co. Ltd.), Megaface F171, F172 and F173 (each manufactured by Dainippon Ink And Chemicals, Incorporated), Fluorad FC430, FC431, FC135 and FC93 (each manufactured by Sumitomo 3M Limited), ASAHI GUARD AG710, Surflon S382, SC101, SC102, SC103, SC104, SC105 and SC106 (each manufactured by Asahi Glass Co., Ltd.), and the like.

In a case where the surfactant (E) is contained, the amount of the surfactant (E) contained with respect to 100 parts by mass of the polymer (A) (or with respect to 100 parts by mass of the total polymer, provided that a polymer other than the polymer (A) is further contained) is preferably no less than 0.001 parts by mass and no greater than 5 parts by mass, and more preferably no less than 0.005 parts by mass and no greater than 1 part by mass. When the amount of the surfactant (E) contained falls within the above range, the coating properties can be effectively improved.

### (F) Adhesion Aid

The adhesion aid (F) is a component that improves adhesiveness to an underlying material. When the composition for forming a resist underlayer film contains the adhesion aid (F), the adhesiveness to a substrate as an underlying material (or other film in contact with the resist underlayer film, in a case where the other film is present between the resist underlayer film and the substrate) can be improved. It is to be noted that the adhesion aid (F) may be used either alone, or in combination of two or more types thereof.

Well-known adhesion aids may be used as the adhesion aid (F).

The amount of the adhesion aid (F) contained with respect to 100 parts by mass of the polymer (A) (or with respect to 100 parts by mass of the total polymer, provided that a polymer other than the polymer (A) is further contained) falls within a range of preferably no less than 0.01 parts by mass and no greater than 10 parts by mass, and more preferably no less than 0.01 parts by mass and no greater than 5 parts by mass.

### Method for Preparation of Composition for Forming Resist Underlayer Film

The composition for forming a resist underlayer film may be prepared by mixing the polymer (A), which is an essential component, the solvent (B), the acid generating agent (C) and the crosslinking agent (D), which are favorable components, as well as the other optional component such as the surfactant (E) and the adhesion aid (F), as needed, in a predetermined ratio.

### Resist Underlayer Film-Forming Method

A resist underlayer film-forming method according to another embodiment of the present invention includes:

(1) applying the composition for forming a resist underlayer film according to the embodiment of the present invention on a substrate to provide a coating film; and

(2) heating the coating film to provide a resist underlayer film.

Examples of the substrate include a silicon wafer, a wafer coated with aluminum, and the like. Moreover, the method for applying the composition for forming a resist underlayer film on the substrate is not particularly limited, and for example, an appropriate process such as a spin-coating process, a cast coating process and a roll coating process may be employed.

Heating of the coating film is typically carried out in an ambient air. The heating temperature falls within a range of typically 150° C. to 500° C., and preferably 200° C. to 450° C. When the heating temperature is less than 150° C., the oxidative crosslinking may not sufficiently proceed, and characteristics necessary for use in the resist underlayer film may not be exhibited. The heating time falls within a range of typically 30 sec to 1,200 sec, and preferably 60 sec to 600 sec.

An oxygen concentration in the heating is preferably no less than 5 vol %. When the oxygen concentration in the heating is low, the oxidative crosslinking of the resist underlayer film may not sufficiently proceed, and characteristics necessary for use in the resist underlayer film may not be exhibited.

The coating film may be preheated at a temperature of 60° C. to 250° C. before being heated at a temperature of 150° C. to 500° C. Although the preheating time in the preheating is not particularly limited, the preheating time is preferably 10 sec to 300 sec, and more preferably 30 sec to 180 sec. When the preheating is carried out to preliminarily evaporate a solvent and make the film dense, dehydrogenation reaction may efficiently proceed.

It is to be noted that in the resist underlayer film-forming method, the resist underlayer film is typically formed through the heating of the coating film; however, in a case where the composition for forming a resist underlayer film contains a photo acid generating agent, the resist underlayer film may also be formed by curing the coating film through a combination of an exposure and heating. Radioactive ray used for the exposure may be appropriately selected from visible rays, ultraviolet rays, far ultraviolet rays, X-rays, electron beams, γ radiations, molecular beams, ion beams, and the like depending on the type of the photo acid generating agent.

### Resist Underlayer Film

A resist underlayer film according to still another embodiment of the present invention is formed from the composition for forming a resist underlayer film according to the embodiment of the present invention using, for example, the aforementioned resist underlayer film-forming method. Since the resist underlayer film is formed from the composition for forming a resist underlayer film according to the embodiment of the present invention, the resist underlayer film sufficiently attains general characteristics required for resist underlayer films such as etching resistance and additionally has superior heat resistance, solvent resistance and flexural resistance. Therefore, the resist underlayer film may be suitably applied to pattern-forming processes that employ a multilayer resist process for semiconductor devices in which miniaturization of patterns has been further in progress.

### Pattern-Forming Method

A pattern-forming method according to yet still another embodiment of the present invention includes:

(1) applying the composition for forming a resist underlayer film according to the embodiment of the present invention on a substrate to provide a resist underlayer film (hereinafter, may be also referred to as “step (1)”);

(2) applying a resist composition on an upper face of the resist underlayer film to provide a resist film (hereinafter, may be also referred to as “step (2)”);

(3) exposing the resist film through selective irradiation with a radioactive ray (hereinafter, may be also referred to as “step (3)”);

(4) developing the exposed resist film to form a resist pattern (hereinafter, may be also referred to as “step (4)”), and

(5) dry-etching the resist underlayer film and the substrate sequentially using the resist pattern as a mask (hereinafter, may be also referred to as “step (5)”).

The pattern-forming method may further include, after the step (1) and before the step (2),

(1′) providing an intermediate layer on the resist underlayer film (hereinafter, may be also referred to as “step (1′)”),

and the step (5) may further include dry-etching the intermediate layer.

### Step (1)

In this step, a resist underlayer film is provided on a substrate using the composition for forming a resist underlayer film according to the embodiment of the present invention. It is to be noted that the same method as the aforementioned method for providing a resist underlayer film may be applied to the method for providing the resist underlayer film. The film thickness of the resist underlayer film provided in the step (1) typically falls within a range of 0.05 μm to 5 μm.

Moreover, the pattern-forming method may further include the step (1′) of providing an intermediate layer (intermediate layer coating film) on the resist underlayer film as needed after the step (1). The intermediate layer as referred to means a layer having a function that is exhibited or not exhibited by the resist underlayer film and/or the resist film in a resist pattern formation, to supplement the function exhibited by the resist underlayer film and/or the resist film or impart to the resist underlayer film and/or the resist film another function that is not exhibited by the resist underlayer film and/or the resist film. For example, when an antireflective film is provided as the intermediate layer, an antireflecting function of the resist underlayer film may be further enhanced.

The intermediate layer may be formed from an organic compound and/or an inorganic oxide. Examples of the organic compound include commercially available products such as “DUV-42”, “DUV-44”, “ARC-28” and “ARC-29” (each manufactured by Brewer Science); “AR-3” and “AR-19” (each manufactured by Lohm and Haas Company); and the like. Examples of the inorganic oxide include commercially available products such as “NFC SOG01”, “NFC SOG04”, “NFC SOG080” (each manufactured by JSR), and the like. Moreover, polysiloxanes, titanium oxides, alumina oxides, tungsten oxides, and the like that are provided through a CVD process may be used.

The method for providing the intermediate layer is not particularly limited, and for example, a coating method, a CVD technique, or the like may be employed. Of these, a coating method is preferred. In a case where the coating method is employed, the intermediate layer may be successively provided after the resist underlayer film is provided. Moreover, the film thickness of the intermediate layer is not particularly limited and may be appropriately selected depending on the function required for the intermediate layer; the film thickness of the intermediate layer falls within a range of preferably 10 nm to 3,000 nm, and more preferably 20 nm to 300 nm.

### Step (2)

In this step, a resist film is provided on the upper face of the resist underlayer film using a resist composition. Specifically, the resist film is provided by applying the resist composition such that a resultant resist film has a predetermined film thickness and thereafter subjecting the resist composition to prebaking to evaporate the solvent in the coating film.

Examples of the resist composition include a positive or negative chemically amplified resist composition that contains a photo acid generating agent; a positive type resist composition that is constituted with an alkali-soluble resin and a quinone diazide based photosensitizing agent; a negative type resist that is constituted with an alkali-soluble resin and a crosslinking agent; and the like.

The total solid content concentration in the resist composition typically falls within a range of 1% by mass to 50% by mass. Moreover, the resist composition is generally used for providing a resist film, for example, after being filtered through a filter with a pore size of about 0.2 μm. It is to be noted that a commercially available resist composition may be used as is in this step.

The method for applying the resist composition is not particularly limited, and examples thereof include a spin-coating method, and the like. Moreover, the temperature of the prebaking may be appropriately adjusted depending on the type of the resist composition used and the like, and the temperature of the prebaking falls within a range of generally 30° C. to 200° C., and preferably 50° C. to 150° C.

### Step (3)

In this step, the resist film is exposed by selective irradiation with a radioactive ray. The radioactive ray for use in the exposure may be appropriately selected from visible rays, ultraviolet rays, far ultraviolet rays, X-rays, electron beams, γ radiations, molecular beams, ion beams and the like, depending on the type of the photo acid generating agent used in the resist composition. Among these, far ultraviolet rays are preferred, and a KrF excimer laser beam (248 nm), an ArF excimer laser beam (193 nm), an F₂ excimer laser beam (wavelength: 157 nm), a Kr₂ excimer laser beam (wavelength: 147 nm), an ArKr excimer laser beam (wavelength: 134 nm), extreme-ultraviolet rays (wavelength: 13 nm, etc.) and the like are more preferred. It is to be noted that the resist pattern may be formed by a process without involving a development step, such as a nanoimprint process.

Post-baking may be carried out after the exposure for the purpose of improving a resolution, a pattern profile, developability, and the like. The temperature of the post-baking may be appropriately adjusted depending on the type of the resist composition used and the like, and the temperature of the post-baking falls within a range of typically 50° C. to 200° C., and preferably 70° C. to 150° C.

### Step (4)

In this step, the exposed resist film is developed to form a resist pattern. A developer solution used in this step may be appropriately selected depending on the type of the resist composition used. Examples of the developer solution include an alkaline aqueous solution that contains sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo[5.4.0]-7-undecene, 1,5-diazabicyclo[4.3.0]-5-nonene, or the like. An appropriate amount of a water soluble organic solvent, e.g., an alcohol such as methanol and ethanol, a surfactant, and the like may be added to the alkaline aqueous solution.

A predetermined resist pattern is formed by the development with the developer solution, followed by washing and drying.

### Step (5)

In this step, a predetermined pattern is formed on the substrate through a multilayer resist process in which, in a case where the step (1′) is involved, the intermediate layer, the resist underlayer film and the substrate are dry-etched sequentially in this order, or in a case where the step (1′) is not involved, the resist underlayer film and the substrate are dry-etched sequentially in this order, using the resist pattern as a mask. Gas plasma such as oxygen plasma and the like may be used in the dry-etching. After the dry-etching, the substrate having a predetermined pattern can be obtained.

Furthermore, in addition to the aforementioned pattern-forming method, the pattern-forming method using the composition for forming a resist underlayer film is also exemplified by a pattern-forming method in which a nanoimprint process is employed, and the like.

### EXAMPLES

Hereinafter, the embodiments of the present invention will be explained in more detail by way of Examples, but the present invention is not in any way limited by Examples.

It is to be noted that the polystyrene equivalent weight average molecular weight (Mw) of the polymer (A) was determined by gel permeation chromatography (detector: differential refractometer) using GPC columns (G2000HXL×2, G3000HXL×1) manufactured by Tosoh Corporation and monodisperse polystyrenes as a standard under analytical conditions involving the flow rate of 1.0 mL/min, the elution solvent of tetrahydrofuran and the column temperature of 40° C. Moreover, each film thickness was determined using a spectroscopic ellipsometer (M2000D, manufactured by J. A. WOOLLAM).

### Synthesis of (A) Polymer

Each polymer was synthesized using compounds represented by the following formulae (M-1) to (M-6).

[chemical structure]

### Synthesis Example 1

### Synthesis of (A-1)

In a separable flask equipped with a thermometer, 30 parts by mass of M-1 and 100 parts by mass of M-5, 260 parts by mass of potassium carbonate as an alkali metal compound and 500 parts by mass of dimethylacetamide as a solvent were blended under a nitrogen atmosphere, and a polycondensation reaction was allowed to proceed at 140° C. for 4 hours with stirring to obtain a reaction liquid. The reaction liquid was filtered, and thereafter methanol was added to the reaction liquid to permit reprecipitation. The resultant precipitates were dried to obtain a polymer (A-1) having a structural unit represented by the following formula. The polymer (A-1) had an Mw of 4,000.

[chemical structure]

### Synthesis Example 2

### Synthesis of (A-2)

In a separable flask equipped with a thermometer, 130 parts by mass of M-2 and 100 parts by mass of M-5, 260 parts by mass of potassium carbonate as an alkali metal compound and 500 parts by mass of dimethylacetamide as a solvent were blended under a nitrogen atmosphere, and a polycondensation reaction was allowed to proceed at 140° C. for 4 hours with stirring to obtain a reaction liquid. The reaction liquid was filtered, and thereafter methanol was added to the reaction liquid to permit reprecipitation. The resultant precipitates were dried to obtain a polymer (A-2) having a structural unit represented by the following formula. The polymer (A-2) had an Mw of 5,000.

[chemical structure]

### Synthesis Example 3

### Synthesis of (A-3)

In a separable flask equipped with a thermometer, 130 parts by mass of M-3 and 100 parts by mass of M-5, 260 parts by mass of potassium carbonate as an alkali metal compound and 500 parts by mass of dimethylacetamide as a solvent were blended under a nitrogen atmosphere, and a polycondensation reaction was allowed to proceed at 140° C. for 4 hours with stirring to obtain a reaction liquid. The reaction liquid was filtered, and thereafter methanol was added to the reaction liquid to permit reprecipitation. The resultant precipitates were dried to obtain a polymer (A-3) having a structural unit represented by the following formula. The polymer (A-3) had an Mw of 4,500.

[chemical structure]

### Synthesis Example 4

### Synthesis of (A-4)

In a separable flask equipped with a thermometer, 140 parts by mass of M-4 and 100 parts by mass of M-5, 260 parts by mass of potassium carbonate as an alkali metal compound and 500 parts by mass of dimethylacetamide as a solvent were blended under a nitrogen atmosphere, and a polycondensation reaction was allowed to proceed at 140° C. for 4 hours with stirring to obtain a reaction liquid. The reaction liquid was filtered, and thereafter methanol was added to the reaction liquid to permit reprecipitation. The resultant precipitates were dried to obtain a polymer (A-4) having a structural unit represented by the following formula. The polymer (A-4) had an Mw of 2,500.

[chemical structure]

### Synthesis Example 5

### Synthesis of (A-5)

In a separable flask equipped with a thermometer, 130 parts by mass of M-1 and 100 parts by mass of M-6, 260 parts by mass of potassium carbonate as an alkali metal compound and 500 parts by mass of dimethylacetamide as a solvent were blended under a nitrogen atmosphere, and a polycondensation reaction was allowed to proceed at 140° C. for 4 hours with stirring to obtain a reaction liquid. The reaction liquid was filtered, and thereafter methanol was added to the reaction liquid to permit reprecipitation. The resultant precipitates were dried to obtain a polymer (A-5) having a structural unit represented by the following formula. The polymer (A-5) had an Mw of 3,500.

[chemical structure]

### Synthesis Example 6

### Synthesis of (A-6)

In a separable flask equipped with a thermometer, 65 parts by mass of M-1, 65 parts by mass of M-2 and 100 parts by mass of M-5, 140 parts by mass of potassium carbonate as an alkali metal compound and 500 parts by mass of dimethylacetamide as a solvent were blended under a nitrogen atmosphere, and a polycondensation reaction was allowed to proceed at 130° C. for 4 hours with stirring to obtain a reaction liquid. The reaction liquid was filtered methanol to obtain a random copolymer (A-6). The random copolymer (A-6) had an Mw of 3,800.

[chemical structure]

### Synthesis Example 7

### Synthesis of (a-1)

Into a separable flask equipped with a thermometer were charged 100 parts by mass of 2,7-dihydroxynaphthalene, 30 parts by mass of formalin, 1 part by mass of p-toluenesulfonic acid and 150 parts by mass of propylene glycol monomethyl ether under a nitrogen atmosphere, and polymerization was allowed to proceed at 80° C. for 6 hours with stirring to obtain a reaction liquid. Thereafter, the reaction liquid was diluted with 100 parts by mass of n-butyl acetate, and the organic layer was washed with a large amount of a mixed solvent of water/methanol (mass ratio: 1/2). Thereafter, the solvents were distilled to obtain a polymer (a-1) having a structural unit represented by the following formula. The polymer (a-1) thus obtained had a weight average molecular weight (Mw) of 1,800.

[chemical structure]

### Preparation of Composition for Forming Resist Underlayer Film

Each component other than the polymer (A) is shown below.

### (B) Solvent

B-1: cyclohexanone

### (C) Acid Generating Agent

Compounds represented by the following formulae (C-1) to (C-3):

[chemical structure]

### (D) Crosslinking Agent

A compound represented by the following formula (D-1) (Nikaluck N-2702, manufactured by Sanwa Chemical Co., Ltd);

A compound represented by the following formula (D-2) (synthesized with reference to Journal of Polymer Science Part A: 2008, Vol. 46, p. 4949);

A compound represented by the following formula (D-3) (MW-100LM, manufactured by Sanwa Chemical Co., Ltd);

A compound represented by the following formula (D-4) (a random copolymer of acenaphthylene with hydroxymethyl acenaphthylene, Mw=3,000) (synthesized with reference to Japanese Unexamined Patent Application, Publication No. 2004-168748).

[chemical structure]

### Example 1

Ten parts by mass of (A-1) as the polymer (A) and 100 parts by mass of (B-1) as the solvent (B) were mixed to obtain a solution. Then, the solution was filtered through a membrane filter with a pore size of 0.1 μm to prepare a composition for forming a resist underlayer film.

### Examples 2 to 11 and Comparative Example 1

Each composition for forming a resist underlayer film was prepared in a similar manner to Example 1 except that the type and the amount (parts by mass) of each component blended were as specified in Table 1. It is to be noted that in Table 1, cells filled with “-” indicate that the corresponding component was not blended.

TABLE 1

| | | | | | (C) Acid | | (D) Cross- | |
|---|---|---|---|---|---|---|---|---|
| | | | | | generating | | linking | |
| | (A) Component | | (B) Solvent | | agent | | agent | |
| | | parts | | parts | | parts | | parts |
| | | by | | by | | by | | by |
| | type | mass | type | mass | type | mass | type | mass |
| Example 1 | A-1 | 10 | B-1 | 100 | — | — | — | — |
| Example 2 | A-2 | 10 | B-1 | 100 | — | — | — | — |
| Example 3 | A-3 | 10 | B-1 | 100 | — | — | — | — |
| Example 4 | A-4 | 10 | B-1 | 100 | — | — | — | — |
| Example 5 | A-5 | 10 | B-1 | 100 | — | — | — | — |
| Example 6 | A-1 | 10 | B-1 | 100 | C-1 | 0.5 | D-1 | 1 |
| Example 7 | A-1 | 10 | B-1 | 100 | C-1 | 0.5 | D-2 | 1 |
| Example 8 | A-6 | 10 | B-1 | 100 | C-1 | 0.5 | D-1 | 1 |
| Example 9 | A-6 | 10 | B-1 | 100 | C-3 | 0.5 | D-3 | 1 |
| Example 10 | A-6 | 10 | B-1 | 100 | C-1 | 0.5 | D-4 | 1 |
| Example 11 | A-1 | 10 | B-1 | 100 | C-2 | 0.5 | D-2 | 1 |
| Comparative | a-1 | 10 | B-1 | 100 | — | — | — | — |
| Example 1 | | | | | | | | |

### Evaluations

A refractive index, an extinction coefficient, etching resistance, heat resistance, solvent resistance, and flexural resistance were determined. The results are shown in Table 2.

### Refractive Index and Extinction Coefficient

Each composition for forming a resist underlayer film prepared above was spin-coated on the surface of a silicon wafer having a diameter of 8 inches that served as a substrate, and thereafter heated at 350° C. for 2 min to form a resist underlayer film having a film thickness of 250 nm. Then, a refractive index and an extinction coefficient at a wavelength of 193 nm of the resist underlayer film thus formed were measured using a spectroscopic ellipsometer (M2000D, manufactured by J. A. WOOLLAM). In a case where the refractive index fell within a range of no less than 1.3 and no greater than 1.6 and the extinction coefficient fell within a range of no less than 0.2 and no greater than 0.8 in the measurement, the resist underlayer film was evaluated to be favorable, whereas in a case where the refractive index and the extinction coefficient did not fall within the respective above ranges, the resist underlayer film was evaluated to be unfavorable.

### Etching Resistance

First, the composition for forming a resist underlayer film was spin-coated on a silicon wafer having a diameter of 8 inches through a spin coating method to provide a resist underlayer film having a film thickness of 300 nm. Thereafter, the resist underlayer film was subjected to an etching treatment (pressure: 0.03 Ton; high frequency power: 3000 W; Ar/CF₄=40/100 sccm; and substrate temperature: 20° C.), and the film thickness of the resist underlayer film after the etching treatment was measured. Then, the etching rate (nm/min) was calculated from the relationship between a decrease of the film thickness and the treatment time, and the proportion of the etching rate of the resist underlayer film according to Examples with respect to that of the resist underlayer film according to Comparative Example was calculated. The smaller value suggests more favorable etching resistance.

### Heat Resistance

Each composition for forming a resist underlayer film was spin-coated on a silicon wafer having a diameter of 8 inches to provide a coating film (resist underlayer film), and the film thickness of the coating film was measured using the spectroscopic ellipsometer (the value of the film thickness acquired in this measurement being designated as X). Next, the resist underlayer film was heated at 350° C. for 120 sec, and the film thickness of the resist underlayer film after the heating was measured using the spectroscopic ellipsometer (the value of the film thickness acquired in this measurement being designated as Y). Then, a percent decrease ΔFT (%) of the film thickness of the resist underlayer film after the heating with respect to the film thickness of the resist underlayer film before the heating (ΔFT (%)=100×(X−Y)/X) was calculated, and the calculated value was defined as heat resistance (%). It is to be noted that the smaller heat resistance (%) suggests that there are less sublimated matter and film degradation products generated in the heating of the resist underlayer film, indicating that the resist underlayer film is more favorable (i.e., having superior heat resistance).

### Solvent Resistance

A resist underlayer film was provided in a similar manner to the formation of the resist underlayer film in the evaluation of the refractive index and extinction coefficient. Then, the substrate having the resist underlayer film provided thereon was immersed in cyclohexanone at room temperature for 10 sec. The film thickness of the resist underlayer film before and after the immersion was measured using the spectroscopic ellipsometer and a rate of change of the film thickness was calculated from the measurements. The rate of change of the film thickness was regarded as an indicator for the solvent resistance. In a case where the rate of change of the film thickness was less than 1%, the solvent resistance was evaluated to be “A” (favorable); in a case where the rate of change of the film thickness was no less than 1% and less than 5%, the solvent resistance was evaluated to be “B” (somewhat favorable); and in a case where the rate of change of the film thickness was no less than 5%, the solvent resistance was evaluated to be “C” (unfavorable).

### Flexural Resistance

A resist underlayer film was provided in a similar manner to the formation of the resist underlayer film in the evaluation of the refractive index and extinction coefficient. Then, a solution of an intermediate layer composition for a three layer resist process (NFC SOG508, manufactured by JSR) was spin-coated on the resist underlayer film, and then heated at 200° C. for 60 sec, followed by heating at 300° C. for 60 sec to provide an intermediate layer coating film having a film thickness of 0.04 μm. Next, a commercially available resist composition was spin-coated on the intermediate layer coating film, and a prebaking was carried out at 100° C. for 60 sec to provide a resist film having a film thickness of 0.1 μm.

Next, the resist film was exposed through a mask for an optimum exposure time using an ArF immersion scanner (lens numerical aperture: 1.30; exposure wavelength: 193 nm; manufactured by NIKON). Next, post-baking was carried out at 100° C. for 60 sec, and thereafter the resist film was developed using a 2.38% by mass aqueous tetramethylammonium hydroxide solution. Thereafter, the developed resist film was washed with water and dried to form a positive type resist pattern. Next, the intermediate layer coating film was subjected to a dry-etching treatment with a carbon tetrafluoride gas using the patterned resist film as a mask and a reactive ion etching apparatus (Telius SCCM, manufactured by Tokyo Electron Limited). When the intermediate layer coating film positioned under the opening portion of the resist film was removed, the etching treatment was stopped, resulting in the transfer of the resist pattern to the intermediate layer coating film.

Next, a dry-etching treatment with a mixed gas of oxygen and nitrogen was carried out using as a mask the intermediate layer coating film having the transferred resist pattern and the etching apparatus. When the resist underlayer film positioned under the opening portion of the intermediate layer coating film was removed, the etching treatment was stopped, resulting in the transfer of the pattern of the intermediate layer coating film to the resist underlayer film. Next, a dry-etching treatment with a mixed gas of carbon tetrafluoride and argon was carried out with the etching apparatus, using as a mask the resist underlayer film having the pattern transferred from the intermediate layer coating film. When 0.1 μm of the silicon oxide film positioned under the opening portion of the resist underlayer film was removed, the etching treatment was stopped.

Then, in the resist underlayer film pattern left on the substrate, the shape of a line-and-space pattern, as generally referred to, in which substantially straight lines were arranged at regular intervals, was observed by an SEM (scanning electron microscope). In this line-and-space pattern, 100 substantially straight lines were arranged at regular intervals, with repeating constant intervals of 84 nm, and this assembly was regarded as one set. On one substrate, 21 sets of the pattern having different line widths were included, with the line widths varying by 1 nm from 50 nm to 30 nm. The line width as referred to herein means the width of one substantially straight line arranged at regular intervals formed with the resist underlayer film. In the pattern of the same configuration on the substrate, the state of the pattern having each line width at arbitrary five points was observed by the SEM. Evaluation on the flexural resistance was made based on the results of the observation. In this regard, the flexural resistance was evaluated as: favorable “A” when all the sidewalls of the patterned lines formed of the resist underlayer film stood straight; and unfavorable “B” when at least one curved sidewall was found.

TABLE 2

| | Refrac- | Extinc- | Etching | Heat | Solvent | Flexural |
|---|---|---|---|---|---|---|
| | tive | tion co- | resis- | resis- | resis- | resis- |
| | index | efficient | tance | tance (%) | tance | tance |
| Example 1 | 1.41 | 0.71 | 0.92 | 12 | A | A |
| Example 2 | 1.41 | 0.60 | 0.87 | 9 | A | A |
| Example 3 | 1.40 | 0.50 | 0.85 | 8 | A | A |
| Example 4 | 1.41 | 0.55 | 0.90 | 11 | A | A |
| Example 5 | 1.41 | 0.65 | 0.91 | 10 | A | A |
| Example 6 | 1.41 | 0.70 | 0.90 | 10 | A | A |
| Example 7 | 1.41 | 0.71 | 0.89 | 10 | A | A |
| Example 8 | 1.34 | 0.52 | 0.86 | 11 | A | A |
| Example 9 | 1.33 | 0.55 | 0.89 | 9 | A | A |
| Example 10 | 1.36 | 0.50 | 0.88 | 8 | A | A |
| Example 11 | 1.40 | 0.70 | 0.89 | 10 | A | A |
| Comparative | 1.40 | 0.40 | 1 | 20 | C | B |
| Example 1 | | | | | | |

As is clear from Table 2, the resist underlayer films formed from the compositions for forming a resist underlayer film of Examples 1 to 11 had a favorable refractive index and extinction coefficient, superior etching resistance, and additionally had superior heat resistance as compared with the resist underlayer film formed from the composition for forming a resist underlayer film of Comparative Example 1. Moreover, the resist underlayer films formed from the compositions for forming a resist underlayer film of the above Examples also had favorable solvent resistance and flexural resistance.

According to the embodiment of the present invention, there can be provided a composition for forming a resist underlayer film that is for use in a multilayer resist process and that is capable of providing a resist underlayer film that sufficiently attains general characteristics such as etching resistance and additionally has superior heat resistance, solvent resistance and flexural resistance; a resist underlayer film formed using the composition and a resist underlayer film-forming method; and a pattern-forming method using the composition. Therefore, the composition for forming a resist underlayer film for use in a multilayer resist process, the resist underlayer film and the resist underlayer film-forming method, and the pattern-forming method according to the embodiment of the present invention may be suitably used in pattern-forming processes that employ a multilayer resist process for semiconductor devices in which miniaturization of patterns has been further in progress.

Obviously, numerous modifications and variations of the present invention are possible in light of the above teachings. It is therefore to be understood that within the scope of the appended claims, the invention may be practiced otherwise than as specifically described herein.

1. A composition for forming a resist underlayer film, comprising a polymer having a structural unit represented by a formula (1): [chemical structure]
wherein in the formula (1),
Ar¹, Ar², Ar³ and Ar⁴ each independently represent a divalent aromatic hydrocarbon group or a divalent heteroaromatic group, wherein a part or all of hydrogen atoms included in the divalent aromatic hydrocarbon group and the divalent heteroaromatic group represented by Ar¹, Ar², Ar³ or Ar⁴ are unsubstituted or substituted;
R¹ represents a single bond or a divalent hydrocarbon group having 1 to 20 carbon atoms, wherein a part or all of hydrogen atoms included in the divalent hydrocarbon group represented by R¹ are unsubstituted or substituted, and wherein the divalent hydrocarbon group represented by R¹ has or does not have an ester group, an ether group or a carbonyl group in a structure thereof;
Y represents a carbonyl group or a sulfonyl group;
m is 0 or 1; and
n is 0 or 1.

2. The composition according to claim 1, wherein Ar¹, Ar², Ar³ and Ar⁴ in the formula (1) are each independently represented by a formula (2): [chemical structure]
wherein in the formula (2),
Q¹ represents an aromatic hydrocarbon group having a valency of (k+2) or a heteroaromatic group having a valency of (k+2);
R² represents a halogen atom, a hydroxy group, a cyano group, a formyl group or a monovalent hydrocarbon group having 1 to 20 carbon atoms, wherein a part or all of hydrogen atoms included in the monovalent hydrocarbon group represented by R² are unsubstituted or substituted with a halogen atom, a hydroxy group, a cyano group or a formyl group; and
k is an integer of 0 to 6,
wherein in a case where k is no less than 2, a plurality of R²s are identical or different.

3. The composition according to claim 1, wherein
m in the formula (1) is 0; or
m in the formula (1) is 1 and R¹ in the formula (1) represents a single bond or is represented by a formula (3): [chemical structure]
wherein in the formula (3),
Q² represents an aromatic hydrocarbon group having a valency of (a+2) or a heteroaromatic group having a valency of (a+2);
Q³ represents an aromatic hydrocarbon group having a valency of (b+2) or a heteroaromatic group having a valency of (b+2);
R³ and R⁴ each independently represent a halogen atom, a hydroxy group or a cyano group;
a is an integer of 0 to 4; and
b is an integer of 0 to 4,
wherein in a case where R³ and R⁴ are each present in a plurality of number, a plurality of R^{a}s are identical or different with each other and a plurality of R⁴s are identical or different with each other.

4. The composition according to claim 1, further comprising a solvent.

5. The composition according to claim 1, wherein the composition is for use in a multilayer resist process.

6. A resist underlayer film formed from the composition according to claim 1.

7. A resist underlayer film-forming method, comprising:
applying the composition according to claim 1 on a substrate to provide a coating film; and
heating the coating film to provide a resist underlayer film.

8. A pattern-forming method, comprising:
applying the composition according to claim 1 on a substrate to provide a resist underlayer film;
applying a resist composition on an upper face of the resist underlayer film to provide a resist film;
exposing the resist film through selective irradiation with a radioactive ray;
developing the exposed resist film to form a resist pattern; and
dry-etching the resist underlayer film and the substrate sequentially using the resist pattern as a mask.

9. The pattern-forming method according to claim 8,
wherein the pattern-forming method further comprises: after providing the resist underlayer film on the substrate and before providing the resist film on the upper face of the resist underlayer film, providing an intermediate layer on the resist underlayer film, and
wherein the dry-etching further comprises dry-etching the intermediate layer.
